(19) United States
(12) Patent Application Publication
(10) Pub. No.: US 2018/0135181 A1
(43) Pub. Date: May 17, 2018

(54) LARGE-AREA LASER HEATING SYSTEM

(71) Applicant: ADNANOTEK CORP., New Taipei City (TW)

(72) Inventor: KAI YANG, NEW TAIPEI CITY (TW)

(21) Appl. No.: 15/353,680

(22) Filed: Nov. 16, 2016

(51) Int. Cl. C23C 16/48; H01S 5/183; H01S 5/024; G01J 5/10; H01S 5/42; C23C 16/52

(52) U.S. Cl. CPC C23C 16/483; H01S 5/183; H01S 5/02423; G01J 2005/103; H01S 5/423; C23C 16/52; G01J 5/10

(57) ABSTRACT

The instant disclosure provides a large-area laser heating system including a laser module, a reaction module and a guiding module. The laser module includes a vertical-cavity surface-emitting laser for emitting a laser beam and a laser adjusting structure connected to the vertical-cavity surface-emitting laser. The incident angle of the laser beam emitted by the vertical-cavity surface-emitting laser is adjusted by the laser adjusting structure. The reaction module includes a sample holder for carrying a sample. The guiding module is connected between the laser module and the reaction module, and the laser beam emitted by the vertical-cavity surface-emitting laser passes through the guiding module and projects onto the surface of the sample.

### BACKGROUND

### 1. Technical Field

The instant disclosure relates to a heating system, in particular, to a large-area laser heating system.

### 2. Description of Related Art

In the semiconductor industry, thin film deposition process is generally used for preparing oxide products and hence, during or after the thin film deposition process, the reaction chamber is filled with oxygen atmosphere. In addition, most of the deposition processes include the heating of the sample to high temperatures in order to form the oxide products.

However, in the existing art, the procedure of heating the sample to high temperatures under oxygen atmosphere has certain difficulties. Since most of the filament materials for performing heating undergo oxidation under an oxygen atmosphere while being heated, the heaters used under an oxygen atmosphere mostly employ infrared lamp or a heater made of platinum, silicon carbide, molybdenum disilicide or Inconel. However, the above heaters still have the disadvantages of high power consumption, short lifetime and difficulties related to maintenance. For example, platinum heaters have shorter lifetime and silicon carbide heaters require regular maintenance. Therefore, the conditions and parameters for performing thin film process must be changed and the stability of the product quality is decreased, or the experimental results are not accurate.

In addition, the heating source provided by the conventional resistance wire heater is radioactive and the impurities in the material of the equipment near to the heater may be released and pollute the products. Alternatively, the material deposited by the thin film deposition process can be released and become impurities in the reaction environment.

Along with the increase of the size of the products prepared by thin film deposition processes, how to effectively achieve the heating of the sample has become an object of study in the industry. Therefore, there is a need for providing a large-area heating system which can be used under oxygen atmosphere.

### SUMMARY

An exemplary embodiment of the present disclosure provides large-area laser heating system comprising a laser module, a reaction module and a guiding module. The laser module comprises at least a vertical-cavity surface-emitting laser for emitting at least a laser beam, and a laser adjusting structure connected to the vertical-cavity surface-emitting laser. The incident angle of the laser beam emitted by the vertical-cavity surface-emitting laser is adjusted by the laser adjusting structure. The reaction module comprises a sample holder for holding a sample. The guiding module connects between the laser module and the reaction module, wherein the laser beam emitted by the vertical-cavity surface-emitting laser passes through the guiding module and projects onto a surface of the sample.

Preferably, the large-area laser heating system according to claim 1, further comprising a cooling module connected to the laser module and the guiding module, wherein the cooling module provides cooling water to cool the laser module and the guiding module.

Preferably, the guiding module is a vertical chamber having a jacket structure for cooling water to pass by.

Preferably, the large-area heating system further comprises a temperature detecting device disposed beside the vertical-cavity surface-emitting laser for directly monitoring the temperature of the sample.

Preferably, the temperature detecting device is an infrared temperature detecting device.

Preferably, the guiding module comprises an optical component, and the laser beam passes through the optical component of the guiding module and focuses on the surface of the sample.

Preferably, the size of the sample carrying by the sample holder is larger than 2 inches.

According to another embodiment of the present disclosure, a large-area laser heating system comprising a laser module, a reaction module and a guiding module. The laser module comprises a plurality of vertical-cavity surface-emitting lasers for emitting a plurality of laser beams, and a laser adjusting structure connected to the plurality of vertical-cavity surface-emitting lasers. The incident angle of each laser beam emitted by the plurality of vertical-cavity surface-emitting lasers is adjusted by the laser adjusting structure. The reaction module comprises a sample holder for carrying a sample. The guiding module is connected between the laser module and the reaction module, in which the plurality of laser beams of the plurality of vertical-cavity surface-emitting lasers passes through the guiding module and is guided to a surface of the sample. An optical axis of each laser beam emitted by the plurality of vertical-cavity surface-emitting lasers slants relative to a central axis of the guiding module.

Preferably, an arrangement of the plurality vertical-cavity surface-emitting lasers of the laser module is arc-shaped.

To sum up, the advantages of the instant disclosure reside in that the large-area laser heating system comprising the structure designs, i.e., a laser module comprising a vertical-cavity surface-emitting laser and a laser adjusting structure, and a guiding module for guiding the laser beam emitted by the laser toward the surface of the sample, can achieve the heating of a large-area sample. Meanwhile, since the laser module used as a heater is disposed outside of the reaction module, the structure design of the instant disclosure can further prevent the influences caused by the reaction gases in the reaction chamber on the heater, thereby increasing the stability of the process and reducing the cost of the process and the maintenance of the system.

In order to further understand the techniques, means and effects of the instant disclosure, the following detailed descriptions and appended drawings are hereby referred to, such that, and through which, the purposes, features and aspects of the instant disclosure can be thoroughly and concretely appreciated; however, the appended drawings are merely provided for reference and illustration, without any intention to be used for limiting the instant disclosure.

### BRIEF DESCRIPTION OF THE DRAWINGS

The accompanying drawings are included to provide a further understanding of the instant disclosure, and are incorporated in and constitute a part of this specification. The drawings illustrate exemplary embodiments of the instant disclosure and, together with the description, serve to explain the principles of the instant disclosure.

FIG. 1 is a three-dimensional schematic view of the large-area laser heating system of the embodiments of the instant disclosure;

FIG. 2 is a sectional view of the large-area laser heating system of the embodiments of the instant disclosure; and

FIG. 3 is a block diagram of the large-area laser heating system of the embodiments of the instant disclosure.

### DESCRIPTION OF THE EXEMPLARY EMBODIMENTS

Reference will now be made in detail to the exemplary embodiments of the instant disclosure, examples of which are illustrated in the accompanying drawings. Wherever possible, the same reference numbers are used in the drawings and the description to refer to the same or like parts.

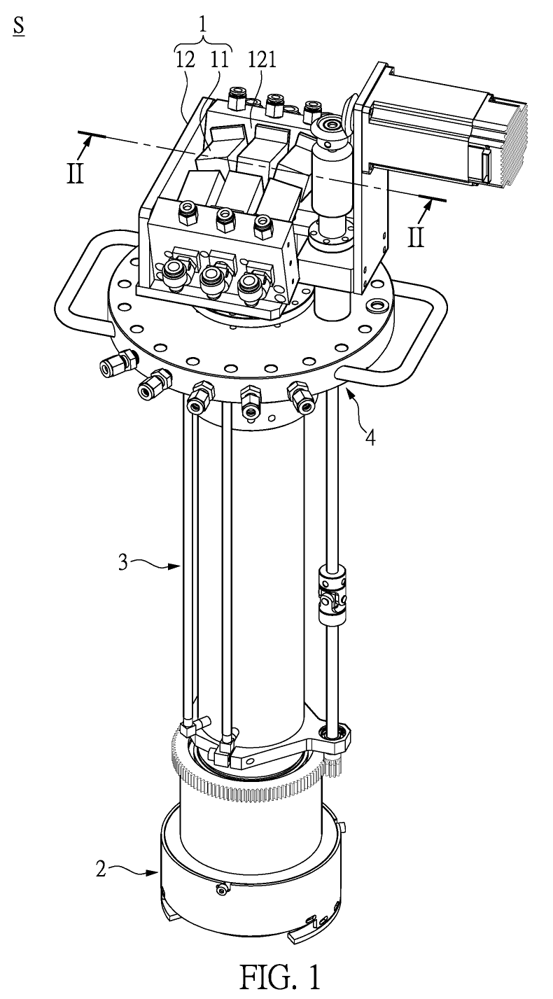

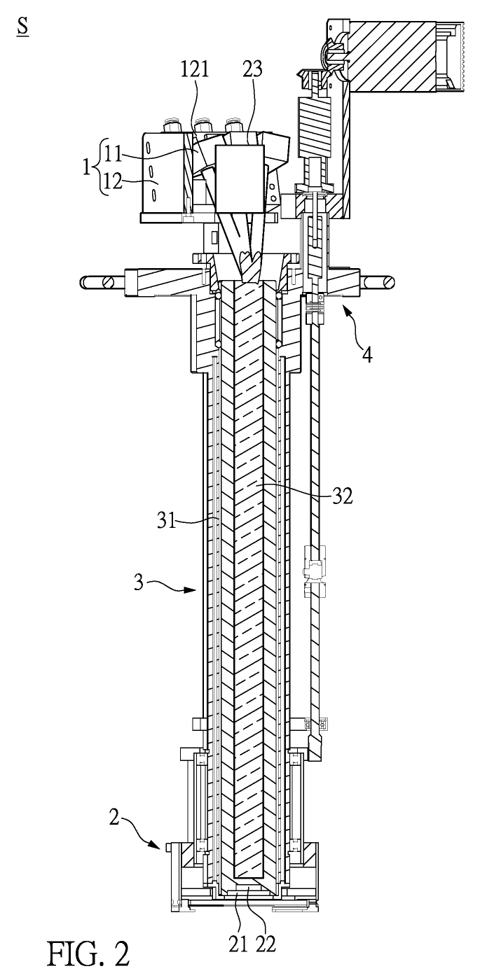

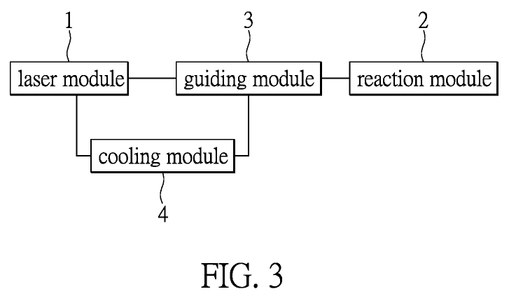

Please refer to FIG. 1 to FIG. 3. FIG. 1 is a three-dimensional schematic view of the large-area laser heating system of the embodiments of the instant disclosure, FIG. 2 is a sectional view of the large-area laser heating system of the embodiments of the instant disclosure, and FIG. 3 is a block diagram of the large-area laser heating system of the embodiments of the instant disclosure. The large-area laser heating system S provided by the embodiments of the instant disclosure comprises a laser module 1, a reaction module 2 and a guiding module 3. As shown in FIG. 1 and FIG. 2, the guiding module 3 is connected between the laser module 1 and the reaction module 2. Specifically, the guiding module 3 is a vertical cavity. The laser module 1 is disposed at the upper end of the guiding module 3 and the reaction module 2 is disposed at the lower end of the guiding module 3. In addition, the reaction module 2 can be sleeved on a part of the guiding module 3, i.e., a part of the reaction module 2 surrounds the lower part of the guiding module 3.

For example, the laser module 1 comprises at least a vertical-cavity surface emitting laser (VSCEL) 11. However, in the instant disclosure, the number of the vertical-cavity surface-emitting laser 11 comprised by the laser module 1 is not limited. In the embodiment shown in FIG. 1 and FIG. 2, the laser module 1 comprises six vertical-cavity surface-emitting lasers 11. In addition, since FIG. 2 is a sectional view taken along the II-II line in FIG. 1, FIG. 2 only shows half of the number of the vertical-cavity surface-emitting laser 11 (i.e., three vertical-cavity surface-emitting lasers 11).

The vertical-cavity surface-emitting laser 11 emits a laser beam (not shown). The VCSEL is a laser diode based on semiconductors which emits a high energy light beam from the top surface thereof along a direction perpendicular to the top surface. Specifically, the main difference between the VCSEL and the conventional laser diode is the relative position between the resonance cavity and the epitaxial layer. In conventional diodes, the resonance cavity and the epitaxial layer are parallel to each other, and the reflective surface is formed by natural fracture and is perpendicular to the epitaxial layer and hence, the laser is emitted from the side surface and is referred to as an “Edge-emitting Laser”. In a vertical-cavity surface-emitting laser, the resonance cavity is perpendicular to the epitaxial layer, and the reflective surface consists of an epitaxial layer or surface dielectric thin film and hence, the laser is emitted from the front side. The vertical-cavity surface-emitting laser has the property of surface-emitting and the advantages of low power consumption and low thermal effect. Therefore, in the embodiments of the instant disclosure, the vertical-cavity surface-emitting laser 11 emits laser light from a surface light source.

In addition, the vertical-cavity surface-emitting laser 11 can be electrically connected to a laser controller (not shown), and the laser controller further comprises a thermometer and a proportional-integral-derivative (PID) temperature controller. The wavelength and energy of the laser beam emitted by the vertical-cavity surface-emitting laser 11 is not limited in the instant disclosure. For example, the wavelength of the laser beam can be 980 nanometers and the energy of the laser beam can be 120 W. The vertical-cavity surface-emitting laser 11 can heat the sample 22 to over 1200° C.

As shown in FIG. 1, the laser module 1 further comprises a laser adjusting structure 12 connected to the vertical-cavity surface-emitting laser 11. The laser adjusting structure 12 is a moving platform which can move along X, Y, Z axes and rotate relative to an axis. Specifically, as shown in FIG. 1 and FIG. 2, the laser adjusting structure 12 can surround a part of the vertical-cavity surface-emitting laser 11 or partially surround the vertical-cavity surface-emitting laser 11 and have at least a bearing surface 121 on which the vertical-cavity surface-emitting laser 11 is fixed. The laser adjusting structure 12 is used for adjusting the emitting angle of the laser beam emitted by the vertical-cavity surface-emitting laser 11, i.e., adjusting the incident light entering the guiding module 3. In other words, in the embodiments of the instant disclosure, the incident angle of the laser beam emitted by the vertical-cavity surface-emitting laser 11 is adjusted by the laser adjusting structure 12.

The laser adjusting structure 12 is connected to a processor (such as a micro-processor) and an external controller for controlling the setting angle and direction of the vertical-cavity surface-emitting laser 11 relative to the guiding module 3. Specifically, by adjusting the inclined degree of the bearing surface 121 of the laser adjusting structure 12 through the processor and the external controller, the incident angle of the laser beam emitted from the vertical-cavity surface-emitting laser 11 can be adjusted. Therefore, when the laser module 1 comprises a plurality of vertical-cavity surface-emitting lasers 11, the optical axes of the plurality of laser beams emitted by the plurality of vertical-cavity surface-emitting lasers 11 respectively can slant relative to the central axis of the guiding module 3. The central axis of the guiding module 3 is an axis passing through the center of the guiding module 3 and perpendicular to the horizontal axis.

When the laser module 1 of the large-area laser heating system S provided by the embodiments of the instant disclosure comprises a plurality of vertical-cavity surface-emitting lasers 11, the relative position between each vertical-cavity surface-emitting laser 11 can be designed to achieve optimum heating efficiency. For example, as shown in FIG. 1 and FIG. 2, the laser module 1 comprises six vertical-cavity surface-emitting lasers 11, and the laser adjusting structure 12 comprises two bearing surfaces 121. Each bearing surface 121 is used to fix three vertical-cavity surface-emitting lasers 11, and the arrangement of the three vertical-cavity surface-emitting lasers 11 fixed on the bearing surface 121 is arc-shaped when observed from the position facing the bearing surface 121. In other words, the light emitting surfaces of each vertical-cavity surface-emitting laser 11 fixed on the same bearing surface 121 are not parallel to each other. Therefore, the light condensing efficiency is improved and the heating uniformity is increased. Alternatively, by adjusting the incident angle of the laser beam, the range of the laser projected onto the sample 22 can be accurately controlled, thereby preventing the problem related to impurity releasing from the material of the equipment caused by oversized heating range.

Under the arrangement of the vertical-cavity surface-emitting lasers 11 relative to the bearing surfaces 121 mentioned above, the inclined degree of the bearing surface 121 can be adjusted through the process and the external controller electrically connected to the laser adjusting structure 12. In other words, by adjusting the inclined degree of the bearing surfaces 121 relative to the horizontal surface, the incident angles of the laser beams emitted from the vertical-cavity surface-emitting lasers 11 fixed on the bearing surfaces 121 can be adjusted.

Next, please refer to FIG. 2. The reaction module 2 comprises a sample holder 21 for carrying the sample 22. The reaction module 2 is a reaction chamber for conducting thin film deposition process. During the thin film deposition process of oxides, the reaction module 2 generally is filled with oxygen atmosphere. The sample holder 21 is disposed at the bottom of the reaction module 2 and carries the sample 22. The type and size of the sample 22 is not limited in the instant disclosure. Preferably, since the instant disclosure employs vertical-cavity surface-emitting laser 11 having surface emitting property as the heating source, the size of the sample 22 can be larger than 2 inches.

The large-area laser heating system S further comprises a temperature detecting device 23 disposed between the plurality of vertical-cavity surface-emitting lasers 11 for directly monitoring the temperature of the sample 22. In other words, the temperature detecting device 23 can be disposed beside the vertical-cavity surface-emitting laser 11. In another embodiment (not shown), the temperature detecting device 23 can be disposed at a position near to the sample holder 21 in the reaction module 2. In existing art, a thermometer using thermocouples is used to indirectly measure the temperature of the heater for achieving temperature monitoring. However, such a means is not accurate and cannot achieve real-time temperature monitoring. Therefore, in the large-area laser heating system S provided by the embodiments of the instant disclosure, the temperature detecting device 23 is directly disposed in the laser module 1 or the reaction module 2 and is an infrared temperature detecting device (such as a thermometer), or a pyrometer sensor. Therefore, the accuracy of the temperature monitoring can be increased and real-time monitoring can be achieved. In addition, according to the temperature detected by the temperature detecting device 23, the laser module 1 of the large-area laser heating system S can be controlled based on the needs of the process or the experiments for controlling the speed of heating or cooling of the sample 22.

As shown in FIG. 1 and FIG. 2, the laser module 1 and the reaction module 2 are connected through the guiding module 3. In other words, the guiding module 3 is connected between the laser module 1 and the reaction module 2. The guiding module 3 is used for the laser beam emitted by the vertical-cavity surface-emitting laser 11 to pass through, thereby guiding the laser beam to the surface of the sample 22. The design of the guiding module 3 can extend the light path of the laser beam, thereby increasing the uniformity of the laser beam projected onto the surface of the sample 22. For example, the guiding module 3 is a vertical chamber comprising an optical component 32, and the laser beam emitted by the vertical-cavity surface-emitting laser 11 passes through the optical component 32 and focuses on the surface of the sample 22. In the embodiment shown in FIG. 2, the optical component 32 is a cylindrical quartz light guide.

During the use of the large-area laser heating system S provided by the embodiments of the instant disclosure, the laser beam emitted by the vertical-cavity surface-emitting laser 11 of the laser module 1 can produce maximum heating power after being focused by the guiding module 3. However, since the laser provides divergent heating, the components of the laser module 1 and the guiding module 3 are irradiated by the laser and the temperatures thereof rises. Therefore, the large-area laser heating system S provided by the embodiments of the instant disclosure further comprises a cooling module 4 connected to the laser module 1 and the guiding module 3 for providing cooling water. The cooling water cools the laser module 1 and the guiding module 3. For example, as shown in FIG. 2, the guiding module 3 has a jacket structure 31 for the cooling water to pass by. Therefore, the cooling module 4 can prevent the impurities in the components of the laser module 1 and the guiding module 3 from releasing and polluting the sample 22.

In summary, the advantages of the instant disclosure reside in that the large-area laser heating system S provided by the embodiments of the instant disclosure which comprises the structure of “a laser module 1 comprising a vertical-cavity surface-emitting laser 11 and a laser adjusting structure 12” and “a guiding module 3 for guiding the laser beam emitted by the vertical-cavity surface-emitting laser 11 to the surface of the sample 22” can achieve heating on large-area samples. Meanwhile, since the laser module 1 used as the heater is disposed outside of the reaction module 2, the large-area laser heating system S provided by the instant disclosure can prevent the reaction gases in the reaction module 2 from influencing the heater, thereby increasing the stability of the process and reducing the cost of the process and maintenance.

The above-mentioned descriptions represent merely the exemplary embodiment of the present disclosure, without any intention to limit the scope of the instant disclosure thereto. Various equivalent changes, alterations or modifications based on the claims of the instant disclosure are all consequently viewed as being embraced by the scope of the instant disclosure.

What is claimed is:

1. A large-area laser heating system, comprising:
a laser module comprising at least a vertical-cavity surface-emitting laser for emitting at least a laser beam, and a laser adjusting structure connected to the vertical-cavity surface-emitting laser, wherein an incident angle of the laser beam emitted by the vertical-cavity surface-emitting laser is adjusted by the laser adjusting structure;
a reaction module comprising a sample holder for holding a sample; and
a guiding module connected between the laser module and the reaction module, wherein the laser beam emitted by the vertical-cavity surface-emitting laser passes through the guiding module and projects onto a surface of the sample.

2. The large-area laser heating system according to claim 1, further comprising a cooling module connected to the laser module and the guiding module, wherein the cooling module provides cooling water to cool the laser module and the guiding module.

3. The large-area laser heating system according to claim 2, wherein the guiding module is a vertical chamber having a jacket structure for cooling water to pass through.

4. The large-area laser heating system according to claim 1, further comprising a temperature detecting device disposed beside the vertical-cavity surface-emitting laser for directly monitoring the temperature of the sample.

5. The large-area laser heating system according to claim 4, wherein the temperature detecting device is an infrared temperature detecting device.

6. The large-area laser heating system according to claim 4, wherein the temperature detecting device is a pyrometer sensor.

7. The large-area laser heating system according to claim 1, wherein the guiding module comprises an optical component, and the laser beam passes through the optical component of the guiding module and focuses on the surface of the sample.

8. The large-area laser heating system according to claim 1, wherein the size of the sample carrying by the sample holder is larger than 2 inches.

9. A large-area laser heating system, comprising:
a laser module comprising a plurality of vertical-cavity surface-emitting lasers for emitting a plurality of laser beams, and a laser adjusting structure connected to the plurality of vertical-cavity surface-emitting lasers, wherein an incident angle of each laser beam emitted by the plurality of vertical-cavity surface-emitting lasers is adjusted by the laser adjusting structure;
a reaction module comprising a sample holder for carrying a sample; and
a guiding module connected between the laser module and the reaction module, wherein the plurality of laser beams of the plurality of vertical-cavity surface-emitting lasers passes through the guiding module and is guided to a surface of the sample;
wherein an optical axis of each laser beam emitted by the plurality of vertical-cavity surface-emitting lasers slants relative to a central axis of the guiding module.

10. The large-area laser heating system according to claim 9, wherein an arrangement of the plurality of vertical-cavity surface-emitting lasers of the laser module is arc-shaped.
